(19) United States
(12) Patent Application Publication
(10) Pub. No.: US 2017/0223849 A1
(43) Pub. Date: Aug. 3, 2017

(54) SUBSEA CONTAINER AND METHOD OF MANUFACTURING THE SAME

(71) Applicant: Siemens Aktiengesellschaft, Muenchen (DE)

(72) Inventor: Roger SKARBOE, Trondheim (NO)

(73) Assignee: Siemens Aktiengesellschaft, Muenchen (DE)

(21) Appl. No.: 15/383,015

(22) Filed: Dec. 19, 2016

(30) Foreign Application Priority Data
Feb. 2, 2016 (EP) 1615383.2.7

(51) Int. Cl. H05K 5/02; E21B 43/01; B65D 90/10; E21B 41/00; B65D 88/78; B65D 81/02

(52) U.S. Cl. CPC H05K 5/0217; B65D 88/78; B65D 81/022; B65D 90/10; E21B 41/0007; E21B 43/01

(57) ABSTRACT

A subsea container is for housing an electronic module. In an embodiment, the subsea container includes a main body including an opening; a module frame for receiving an electronic module that is to be arranged inside the main body; a support structure for supporting the module frame within the main body; and a lid fitting the opening of the main body, the support structure including a shock absorbing structure. Further, a method of manufacturing a subsea container is described.

### PRIORITY STATEMENT

The present application hereby claims priority under 35 U.S.C. §119 to European patent application number EP 16153832.7 filed Feb. 2, 2016, the entire contents of which are hereby incorporated herein by reference.

### FIELD

At least one embodiment of the present invention generally relates to the field of subsea devices, in particular subsea containers for electronic equipment.

### BACKGROUND

In subsea installations, such as installations for oil or gas production, various electric and electronic installations need to be placed at the bottom of the sea. This is often done by arranging the installations in subsea containers or canisters, which typically consist of a metal cylinder with a single opening closed by a lid. The electronics are typically mounted in a rack or similar module structure which is fastened on the inner side of the lid, e.g. via screws. Although these containers provide good protection against the sea water, they are in some cases susceptible to shock and vibration. More specifically, significant bending forces may impact the electronics causing wear and potential damage.

### SUMMARY

The inventors have recognized that there is a need exists for an improved subsea container which is capable of providing excellent protection at a reasonable price.

Advantageous embodiments of the present invention are described by the claims.

According to a first embodiment of the invention there is provided a subsea container for housing an electronic module. The subsea container comprises (a) a main body having an opening, (b) a module frame for receiving an electronic module that is to be arranged inside the main body, (c) a support structure for supporting the module frame within the main body, and (d) a lid fitting the opening of the main body, wherein the support structure comprises a shock absorbing structure.

According to a second embodiment of the invention there is provided a subsea system comprising (a) at least one subsea container according to the first aspect or any the preceding embodiments, (b) a subsea network, and (c) at least one subsea production unit, wherein the at least one subsea container houses an electronic module which is in communication with the at least one subsea production unit via the subsea network.

According to a third embodiment of the invention there is provided a method of manufacturing a subsea container for housing an electronic module. The method comprises (a) providing a main body having an opening, (b) providing a module frame for receiving an electronic module that is to be arranged inside the main body, (c) providing a support structure for supporting the module frame within the main body, and (d) providing a lid fitting the opening of the main body, wherein the support structure comprises a shock absorbing structure.

It is noted that embodiments of the invention have been described with reference to different subject matters. In particular, some embodiments have been described with reference to method type claims whereas other embodiments have been described with reference to apparatus type claims. However, a person skilled in the art will gather from the above and the following description that, unless otherwise indicated, in addition to any combination of features belonging to one type of subject matter also any combination of features relating to different subject matters, in particular to combinations of features of the method type claims and features of the apparatus type claims, is part of the disclosure of this document.

The aspects defined above and further aspects of the present invention are apparent from the examples of embodiments to be described hereinafter and are explained with reference to the examples of embodiments. The invention will be described in more detail hereinafter with reference to examples of embodiments. However, it is explicitly noted that the invention is not limited to the described example embodiments.

### BRIEF DESCRIPTION OF THE DRAWINGS

FIG. 1 shows a side view of a subsea container according to an example embodiment of the present invention.

FIG. 2 shows a side cross-sectional view of the subsea container shown in FIG. 1.

FIG. 3 shows an end cross-sectional view of the subsea container shown in FIGS. 1 and 2.

FIG. 4 shows an end cross-sectional view of a subsea container according to a further example embodiment of the present invention.

### DETAILED DESCRIPTION OF THE EXAMPLE EMBODIMENTS

In the following, embodiments of the invention are described in detail with reference to the accompanying drawings. It is to be understood that the following description of the embodiments is given only for the purpose of illustration and is not to be taken in a limiting sense. It should be noted that the drawings are to be regarded as being schematic representations only, and elements in the drawings are not necessarily to scale with each other. Rather, the representation of the various elements is chosen such that their function and general purpose become apparent to a person skilled in the art.

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Various example embodiments will now be described more fully with reference to the accompanying drawings in which only some example embodiments are shown. Specific structural and functional details disclosed herein are merely representative for purposes of describing example embodiments. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Accordingly, known processes, elements, and techniques, may not be described with respect to some example embodiments. Unless otherwise noted, like reference characters denote like elements throughout the attached drawings and written description, and thus descriptions will not be repeated. The present invention, however, may be embodied in many alternate forms and should not be construed as limited to only the example embodiments set forth herein.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “connected,” “engaged,” “interfaced,” and “coupled.” Unless explicitly described as being “direct,” when a relationship between first and second elements is described in the above disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “exemplary” is intended to refer to an example or illustration.

When an element is referred to as being “on,” “connected to,” “coupled to,” or “adjacent to,” another element, the element may be directly on, connected to, coupled to, or adjacent to, the other element, or one or more other intervening elements may be present. In contrast, when an element is referred to as being “directly on,” “directly connected to,” “directly coupled to,” or “immediately adjacent to,” another element there are no intervening elements present.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Before discussing example embodiments in more detail, it is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments of the present invention. This invention may, however, be embodied in many alternate forms and should not be construed as limited to only the embodiments set forth herein.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

According to a first embodiment of the invention there is provided a subsea container for housing an electronic module. The subsea container comprises (a) a main body having an opening, (b) a module frame for receiving an electronic module that is to be arranged inside the main body, (c) a support structure for supporting the module frame within the main body, and (d) a lid fitting the opening of the main body, wherein the support structure comprises a shock absorbing structure.

This embodiment of the invention is based on the idea that the module frame (i.e. a part on or in which the electronic module can be mounted, also referred to as a rack) is supported by a shock absorbing structure, such that the impact on the module frame caused by shock and vibration applied to the subsea container, in particular to the main body and/or to the lid (e.g. while bringing the container in place on the bottom of the sea or later on due to stream etc.) is attenuated significantly. Thereby, wear, damage and malfunction of the electronic module caused by vibration or shock can be reduced significantly or even prevented.

The main body and the lid form the actual container, i.e. the outer wall that protects the electronic module against sea water, and are made from a suitable material that is capable of withstanding salt water, such as metal. The wall thickness is generally chosen in dependency of the inner volume of the container and the outside pressure at the place of use, such as on the bottom of the ocean, e.g. at 2 km or more below sea level. Typically, the wall thickness may be between 1 cm and 5 cm, such as between 2 and 4 cm, such as around 3 cm. However, other values are possible. The opening in the main body serves to allow insertion of the module frame containing the relevant electronic module before the lid is mounted to close the container. The support structure serves to keep the module frame (and thereby the electronic module) in place inside the subsea container.

In the present context, the term “electronic module” may in particular denote an assembly of any number of electronic components, such as resistors, inductors, capacitors, diodes, transistors, logic chips, microprocessors, transformers, etc., e.g. arranged on one or more PCBs, and designed to perform one or more specific functions, such as control of subsea equipment or measurement. As such, an electronic module may consist of several sub-modules.

According to an embodiment of the invention, the shock absorbing structure is arranged on an inner wall of the main body.

In other words, the shock absorbing structure (as part of the support structure) is arranged such that it is located between the wall of the main body and the module frame. Thereby, the shock absorbing structure can effectively dampen or attenuate the impact on the module frame that occurs when the container receives sudden blows or when the container is exposed to sudden movements or vibrations.

According to a further embodiment of the invention, the shock absorbing structure comprises a plurality of shock absorbing units.

In another embodiment, the shock absorbing units are distributed over the inner surface of the main body and are furthermore connected to (e.g. by screws) or at least in contact with the module frame.

According to a further embodiment of the invention, the shock absorbing units are arranged on a curve, such as a circle, surrounding the module frame.

In other words, the shock absorbing units are arranged on a curve or line that form a closed loop around the module frame. Thereby, the shock absorbing units provide support and shock absorption around the module frame at a particular axial position of the module frame. Depending e.g. on whether an even or uneven number of shock absorbing units are used, the support and shock absorption may be provided in a symmetrical or asymmetrical manner.

According to a further embodiment of the invention, a first part of the shock absorbing units are arranged on a first curve, such as a first circle, surrounding the module frame and a second part of the shock absorbing units are arranged on a second curve, such as a second circle, surrounding the module frame.

In other words, the shock absorbing units are arranged in two separate groups, such that each group forms a closed loop around the module frame. For example, the first part or group of shock absorbing units may be arranged at a predetermined distance from the second part or group of shock absorbing units in the direction of a longitudinal axis of the module frame. Thereby, further the support and shock absorbing effects can be further improved and other elements (such as screws) for fastening the module frame may to some extent be dispensed with.

According to a further embodiment of the invention, the shock absorbing units comprise a material, such as rubber, having a Shore A hardness between 50 and 80, such as between 55 and 75, such as between 60 and 70, such as around 65.

Such shock absorbing units are readily available, reasonably priced and easy to use. Furthermore, experiments have shown that a shock absorbing structure using such shock absorbing units has excellent properties and characteristics. In particular, a support structure comprising such shock absorbing structure does not show any strong resonances (with amplification larger than five) at frequencies below 150 Hz and therefore provide excellent support and shock absorption in subsea applications.

According to a further embodiment of the invention, the main body has a cylindrical shape, in particular circular cylindrical, rectangular cylindrical or quadratic cylindrical, although other cylindrical shapes are also possible and encompassed by the present disclosure.

According to a further embodiment of the invention, the support structure further comprises a plurality of screws for securing the module frame to the shock absorbing structure and/or to the lid and/or to the main body.

As additional support, screws may be used to secure the module frame at various locations within the container. The screws may serve to fasten the module frame to one or more of the shock absorbing structure, the lid and the main body in order to further increase the stability of the support structure.

According to a further embodiment of the invention, the support structure further comprises one or more guiding elements for guiding the module frame within the main body.

In particular, the one or more guiding elements may be implemented as recesses or protrusions which are shaped to mate with corresponding protrusions or recesses formed in the module frame. Thereby, insertion of the module frame into the main body is facilitated.

According to a further embodiment of the invention, the module frame comprises a protruding element and the lid comprises a recess adapted to receive the protruding element.

To further increase the stability of the module frame when arranged in the subsea container, the lid may according to this embodiment have a recess mating a protruding element of the module frame. Thus, when the lid is arranged to close the opening of the main body after insertion of the module frame (with the electronic module), the protrusion fits into the recess and increased stability and support is provided.

It goes without saying that the same effect may be obtained by providing the protruding element in the lid and providing the recess in the module frame.

According to a second embodiment of the invention there is provided a subsea system comprising (a) at least one subsea container according to the first aspect or any the preceding embodiments, (b) a subsea network, and (c) at least one subsea production unit, wherein the at least one subsea container houses an electronic module which is in communication with the at least one subsea production unit via the subsea network.

This embodiment of the invention relies on the above described features and advantages of the subsea container according to the present invention to provide an improved subsea system with increased durability and shock resistance.

According to a third embodiment of the invention there is provided a method of manufacturing a subsea container for housing an electronic module. The method comprises (a) providing a main body having an opening, (b) providing a module frame for receiving an electronic module that is to be arranged inside the main body, (c) providing a support structure for supporting the module frame within the main body, and (d) providing a lid fitting the opening of the main body, wherein the support structure comprises a shock absorbing structure.

This embodiment of the invention is based on the same idea as the first and second aspects described above, namely that of reducing wear, damage and malfunction of electronic modules arranged within subsea containers by utilizing a shock absorbing support structure to support a module frame within the main body of the subsea container.

It is noted that embodiments of the invention have been described with reference to different subject matters. In particular, some embodiments have been described with reference to method type claims whereas other embodiments have been described with reference to apparatus type claims. However, a person skilled in the art will gather from the above and the following description that, unless otherwise indicated, in addition to any combination of features belonging to one type of subject matter also any combination of features relating to different subject matters, in particular to combinations of features of the method type claims and features of the apparatus type claims, is part of the disclosure of this document.

The illustration in the drawing is schematic. It is noted that, in different figures, similar or identical elements are provided with the same reference numerals or with reference numerals which differ only within the first digit.

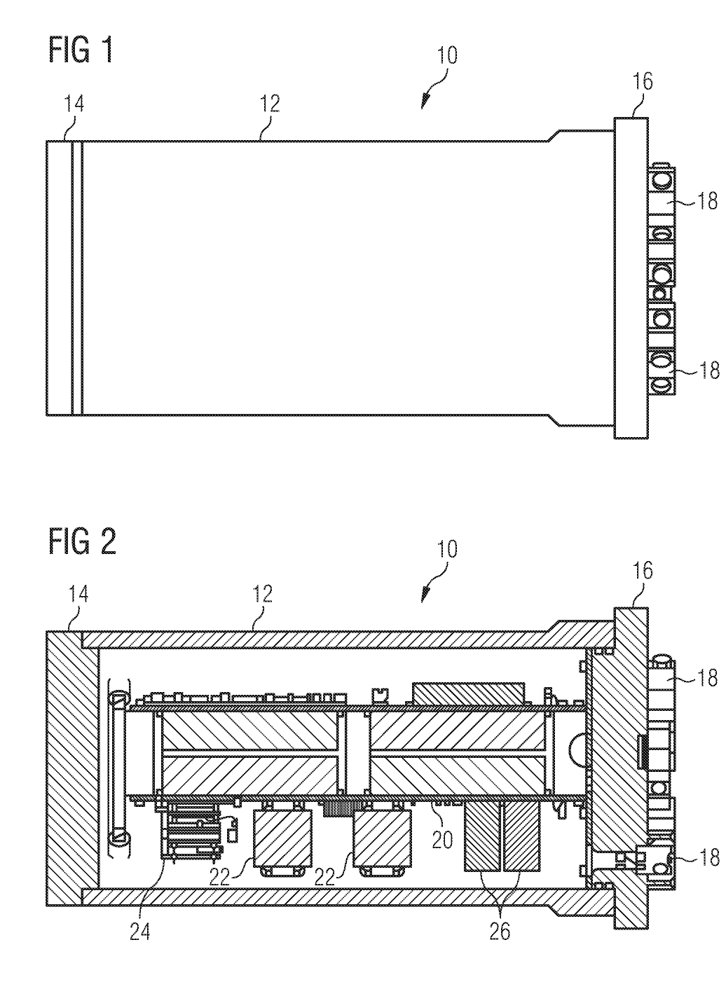

FIG. 1 shows a side external view of a subsea container 10 according to an example embodiment of the present invention. As shown, the subsea container 10 generally has an elongate shape and comprises a cylindrical portion 12, an end portion 14 that closes the cylindrical portion 12 at one end, a lid 16 and penetrator/back shell 18. The penetrator/back shell 18 allows cables and wires to extend through the lid 16. The cylindrical portion 12 and the end portion 14 form a main body of the subsea container 10. The lid fits the opening at the end of the cylindrical portion 12 that is opposite to the end portion 14 and is fastened to the main body by screws or bolts (not shown) such that the subsea container is completely sealed. Depending on the specific application, the subsea container 10 has a length (horizontal direction in FIG. 1) between 0.5 m and 1.5 m, such as around 1 m. The diameter of the cylindrical portion is typically about half the length, i.e. around 0.5 m. Cylindrical portion 12, end portion 14 and lid 16 are all made of salt water resistant material, such as steel. The parts forming the walls of subsea container 10, i.e. cylindrical portion 12, end portion 14, and lid 16 are sufficiently thick to withstand the high pressure at depths of several kilometers below sea level, typically between 1 cm and 5 cm thick.

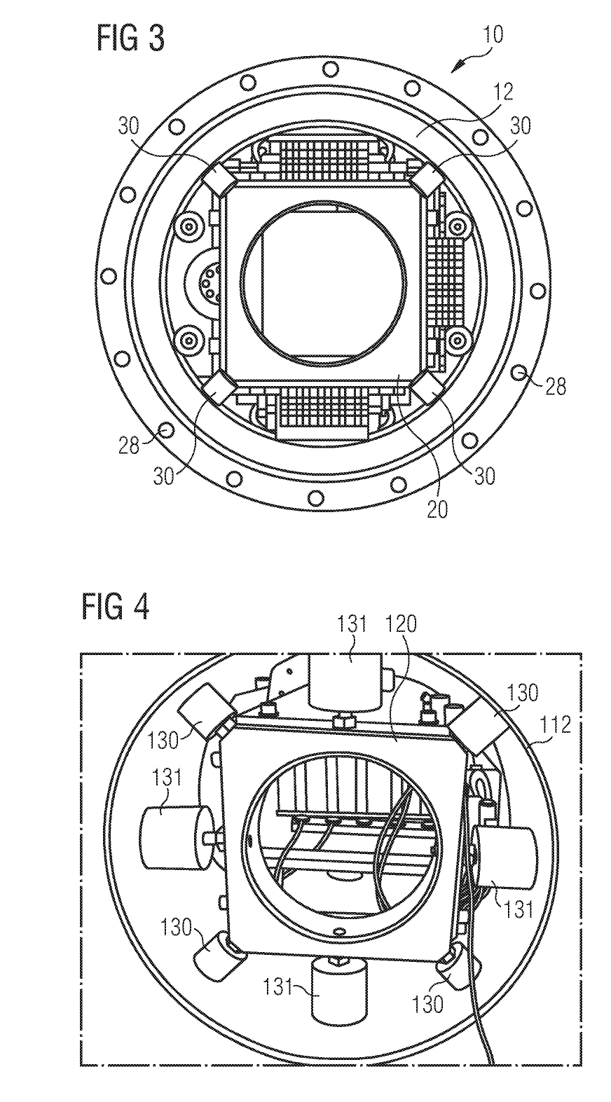

FIG. 2 shows a side cross-sectional view of the subsea container 10 shown in FIG. 1. Apart from the parts already discussed above in conjunction with FIG. 1, FIG. 2 shows a module frame 20 arranged inside the cylindrical portion 12 of the subsea container 10. The module frame 20 is a stable (e.g. metallic) frame for carrying electric and electronic components 22, 24, 26 which together form an electronic module. The module frame 20 is supported within the subsea container 10 by a support structure which will be discussed in detail further below with reference to FIG. 3 and FIG. 4.

FIG. 3 shows an end cross-sectional view of the subsea container 10 shown in FIGS. 1 and 2 and discussed above. More specifically, FIG. 3 shows the subsea container 10 without the lid 16. The holes 28 on the outer perimeter of the end face of the cylindrical portion 12 allow fastening the lid 16 with bolts and nuts (not shown). As noted above, the module frame 20 is supported within the subsea container 10 by a support structure. As shown in FIG. 3, the support structure comprises four shock absorbing units 30 which are evenly distributed along a circle on the inner wall of the cylindrical portion 12. More specifically, the shock absorbing units 30 are arranged such that each unit 30 is connected (e.g. screw mounted) to a corner portion of the essentially square-shaped module frame 20. The shock absorbing units 30 preferably comprise hard rubber or similar material with a Shore A hardness around 60.

The support structure may contain further shock absorbing units (not shown) arranged deeper within the subsea container 20. Furthermore, the support structure may also contain further support and/or fastening elements (not shown), such as screws, nuts, mating protrusions and recesses, etc.

In sum, the support structure in the subsea container according to the embodiment illustrated in FIGS. 1 to 3 and discussed above provide effective dampening of shocks and vibrations and does not show any notable resonance phenomena at frequencies below 150 Hz. Thereby, wear of the electronic components and modules carried by the module frame 20 is significantly reduced, which in turn leads to reduced risk of damage as well as extended lifetime of the electronic module.

FIG. 4 shows an end cross-sectional view of a subsea container according to a further example embodiment of the present invention. It is noted that the overall structure of the subsea container corresponds to that described above in conjunction with FIGS. 1 to 3. However, the embodiment shown in FIG. 4 differs in the support structure comprising four shock absorbing units 130 arranged between the inner wall of the cylindrical portion 112 and corner portions of the module frame 120 (similar to the arrangement shown in FIG. 3) and an additional four shock absorbing units 131 arranged between the inner wall of the cylindrical portion 112 and side portions of the module frame 120. By adding the additional shock absorbing units 131 between the four shock absorbing units 130, the dampening is further improved. As shown, the additional shock absorbing units 131 are larger (both longer and wider) than the shock absorbing units 130.

It is noted that the term “comprising” does not exclude other elements or steps and the use of the articles “a” or “an” does not exclude a plurality. Also elements described in association with different embodiments may be combined. It is further noted that reference signs in the claims are not to be construed as limiting the scope of the claims.

The patent claims of the application are formulation proposals without prejudice for obtaining more extensive patent protection. The applicant reserves the right to claim even further combinations of features previously disclosed only in the description and/or drawings.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

None of the elements recited in the claims are intended to be a means-plus-function element within the meaning of 35 U.S.C. §112(f) unless an element is expressly recited using the phrase “means for” or, in the case of a method claim, using the phrases “operation for” or “step for.”

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. A subsea container for housing an electronic module, the subsea container comprising:
a main body including an opening;
a module frame to receive an electronic module, arrangeable inside the main body,
a support structure to support the module frame within the main body; and
a lid, to fit the opening of the main body, wherein the support structure includes a shock absorbing structure.

2. The subsea container of claim 1, wherein the shock absorbing structure is arranged on an inner wall of the main body.

3. The subsea container of claim 1, wherein the shock absorbing structure includes a plurality of shock absorbing units.

4. The subsea container of claim 3, wherein the shock absorbing units are arranged on a curve surrounding the module frame.

5. The subsea container of claim 3, wherein a first part of the shock absorbing units are arranged on a first curve surrounding the module frame and a second part of the shock absorbing units are arranged on a second curve surrounding the module frame.

6. The subsea container of claim 3, wherein the shock absorbing units comprise a material having a Shore A hardness between 50 and 80.

7. The subsea container of claim 1, wherein the main body has a cylindrical shape.

8. The subsea container of claim 1, wherein the support structure further comprises a plurality of screws for securing the module frame to at least one of the shock absorbing structure, the lid and the main body.

9. The subsea container of claim 1, wherein the support structure further comprises one or more guiding elements for guiding the module frame within the main body.

10. The subsea container of claim 1, wherein the module frame comprises a protruding element and wherein the lid comprises a recess adapted to receive the protruding element.

11. A subsea system comprising
at least one of the subsea container of claim 1;
a subsea network; and
at least one subsea production unit,
wherein the at least one subsea container houses an electronic module, configured to communicate with the at least one subsea production unit via the subsea network.

12. A method of manufacturing a subsea container for housing an electronic module, the method comprising:
providing a main body including an opening;
providing a module frame to receive an electronic module, arrangeable inside the main body;
providing a support structure to support the module frame within the main body; and
providing a lid to fit the opening of the main body,
wherein the support structure includes a shock absorbing structure.

13. The subsea container of claim 2, wherein the shock absorbing structure includes a plurality of shock absorbing units.

14. The subsea container of claim 13, wherein the shock absorbing units are arranged on a curve surrounding the module frame.

15. The subsea container of claim 13, wherein a first part of the shock absorbing units are arranged on a first curve surrounding the module frame and a second part of the shock absorbing units are arranged on a second curve surrounding the module frame.

16. The subsea container of claim 4, wherein the shock absorbing units comprise a material having a Shore A hardness between 50 and 80.

17. The subsea container of claim 5, wherein the shock absorbing units comprise a material having a Shore A hardness between 50 and 80.

18. The subsea container of claim 13, wherein the shock absorbing units comprise a material having a Shore A hardness between 50 and 80.

19. A subsea system comprising
at least one of the subsea container of claim 3;
a subsea network; and
at least one subsea production unit,
wherein the at least one subsea container houses an electronic module, configured to communicate with the at least one subsea production unit via the subsea network.

20. A subsea system comprising
at least one of the subsea container of claim 5;
a subsea network; and
at least one subsea production unit,
wherein the at least one subsea container houses an electronic module, configured to communicate with the at least one subsea production unit via the subsea network.
